(19) United States
(12) Patent Application Publication
(10) Pub. No.: US 2015/0181734 A1
(43) Pub. Date: Jun. 25, 2015

(54) CARD LOADING ASSEMBLY AND ELECTRONIC DEVICE HAVING THE SAME

(71) Applicants: Fu Tai Hua Industry (Shenzhen) Co., Ltd., Shenzhen (CN); Hon Hai Precision Industry Co., Ltd., New Taipei (TW)

(72) Inventor: YAN-BANG CAO, Shenzhen (CN)

(21) Appl. No.: 14/485,244

(22) Filed: Sep. 12, 2014

(30) Foreign Application Priority Data
Dec. 20, 2013 (CN) 2013107072754

(51) Int. Cl. H05K 5/02

(52) U.S. Cl. CPC H05K 5/0295

(57) ABSTRACT

A card loading assembly is received in a casing for placing a digital card. The casing defines a sliding slot. The card loading assembly includes a tray and a limiting assembly. The tray can rotate with respect to the casing, and defines a positioning recess and a receiving groove. The receiving groove is configured to receive the digital card, and can be rotated out of the casing through the sliding slot. The limiting assembly includes a limiting member and an elastic member. When the tray is received in the casing, the limiting member can be inserted into the positioning recess under a force of the elastic member, thereby positioning the tray with respect to the casing.

### FIELD

The present disclosure relates to card loading assemblies and, particularly, to a card loading assembly for loading a digital card and an electronic device including the card loading assembly.

### BACKGROUND

Many portable devices may include trays for placing digital cards such as memory cards or subscriber identity module (SIM) cards. Typically, such a tray can be pulled out of the electronic device to allow a user to place a digital card therein.

### BRIEF DESCRIPTION OF THE DRAWINGS

Many aspects of the embodiments with this disclosure can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the views. The description is not to be considered as limiting the embodiments described herein or the appended claims.

FIG. 1 is an isometric view of an embodiment of an electronic device.

FIG. 2 is an isometric view of a card loading assembly included in the electronic device of FIG. 1.

FIG. 3 is an exploded isometric view of the electronic device of FIG. 2.

FIG. 4 is a cross-sectional view taken along line IV-IV of FIG. 2.

FIG. 5 is similar to FIG. 2, but showing that a tray is rotated out of the card loading assembly.

### DETAILED DESCRIPTION

The present disclosure, including the accompanying drawings, is illustrated by way of examples and not by way of limitation. The term “comprising,” when utilized, means “including, but not necessarily limited to”; it specifically indicates open-ended inclusion or membership in the so-described combination, group, series and the like.

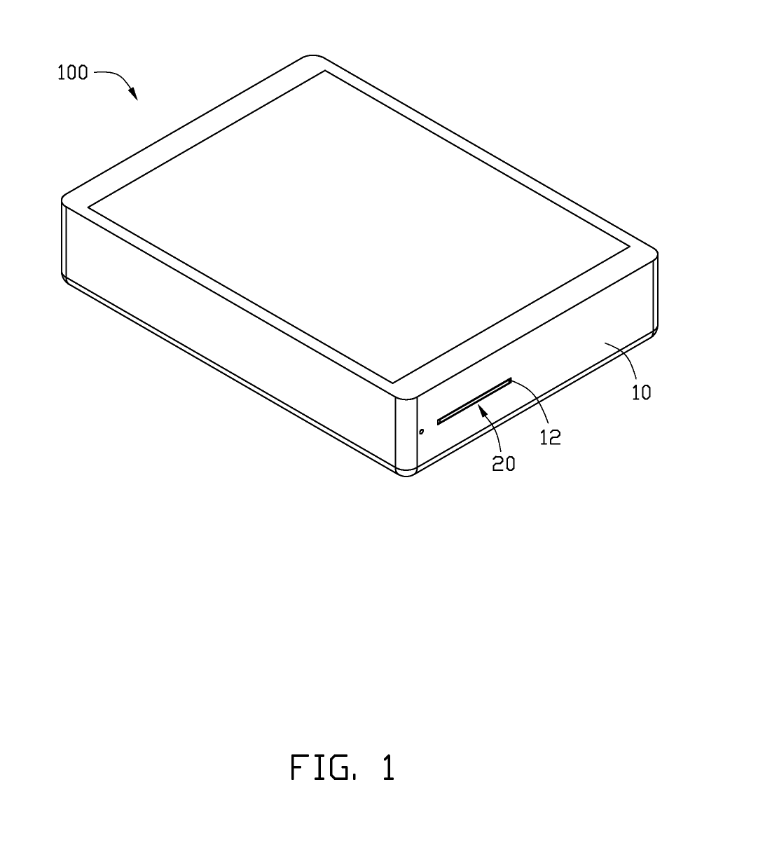

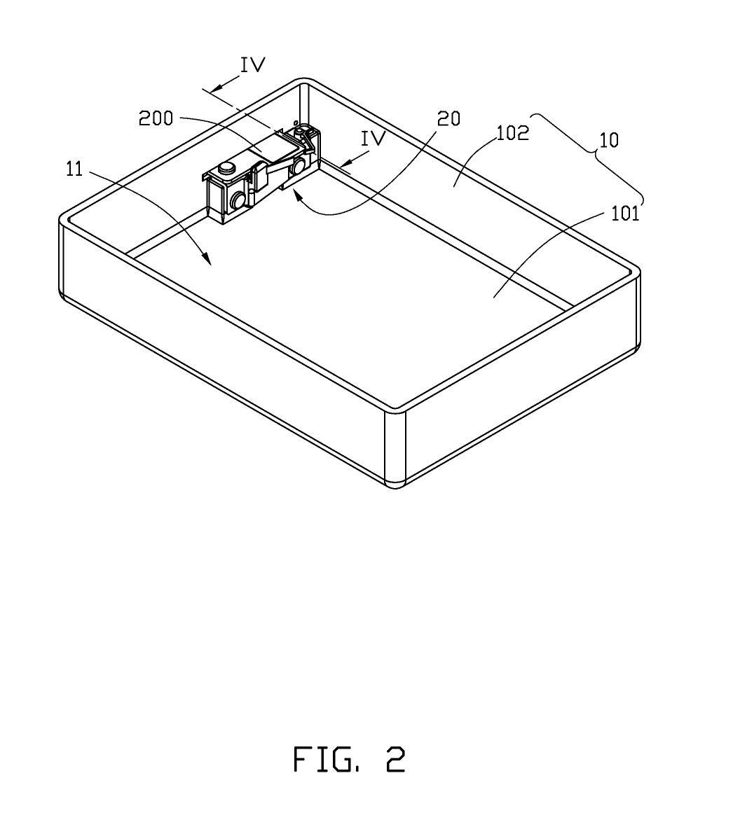

FIGS. 1-2 illustrate an embodiment of an electronic device 100 including a casing 10 and a card loading assembly 20 received in the casing 10. The electronic device 100 can be a cell phone or a tablet computer, for example. The card loading assembly 20 can be used to hold a digital card 200 such as a memory card or SIM card. The casing 10 can include a bottom surface 101 and four sidewalls 102 surrounding the bottom surface 101. The bottom surface 101 and the four sidewalls 102 can cooperatively form a receiving space 11 for receiving the card loading assembly 20 and other electronic elements (not shown) of the electronic device 100, such as a circuit board.

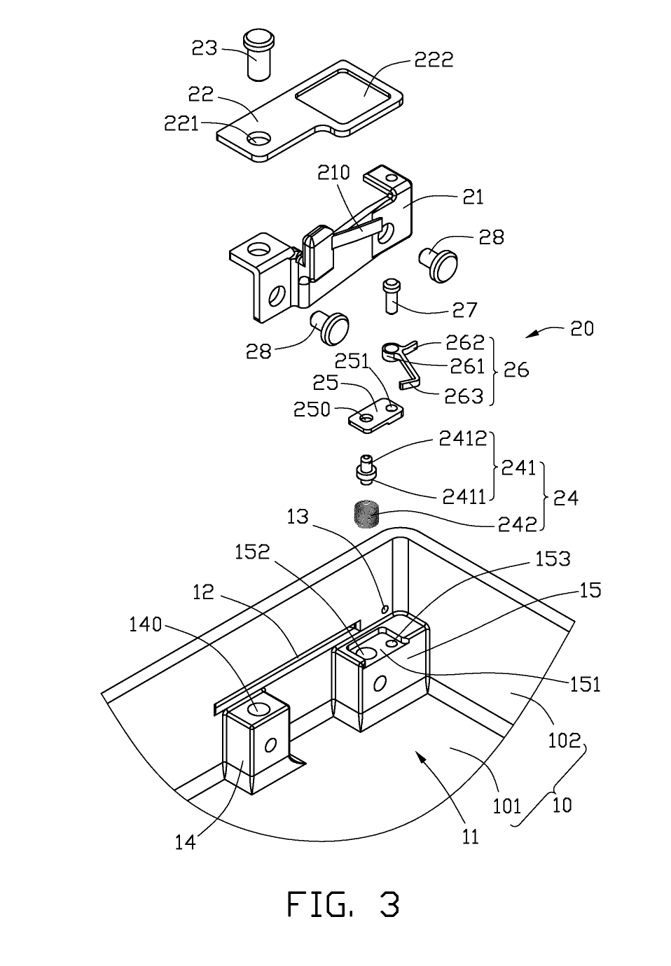

FIG. 3 illustrates that one of the sidewalls 102 can define a sliding slot 12 and a through hole 13 communicating with the receiving space 11. A first fixing block 14 and a second fixing block 15 can be attached to the bottom surface 101, and further attached to an internal surface of the sidewall 102 defining the sliding slot 12. The first and the second fixing blocks 14, 15 can be adjacent to the sliding slot 12. A top of the first fixing block 14 can define a first fixing hole 140. A top of the second fixing block 15 can define a recessed portion 151. A bottom of the recessed portion 151 can define a blind hole 152 and a second fixing hole 153.

The card loading assembly 20 can include a cover 21, a tray 22, a first shaft 23, a limiting assembly 24, a spacer 25, an operating member 26, a second shaft 27, and two fixing elements 28. The cover 21 can be secured to the first and the second fixing blocks 14, 15 via the two fixing elements 28, such as bolts, and can include a second elastic member 210 aligned with the sliding slot 12. In at least one embodiment, the second elastic member 210 can be a substantially rectangular leaf spring.

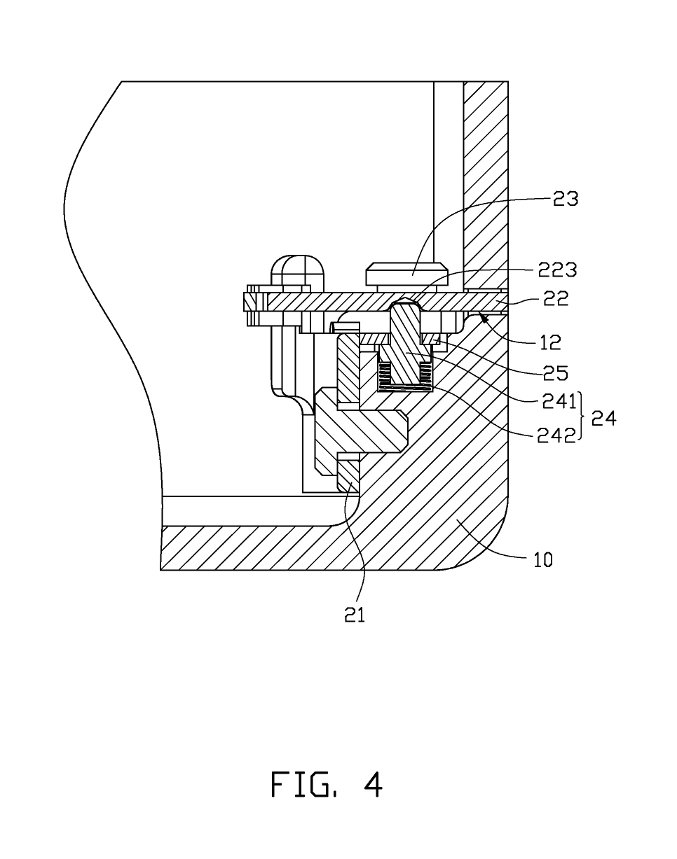

The tray 22 can define a first shaft hole 221 at one end, and define a receiving groove 222 at an opposite end for receiving the SIM card 200. The tray 22 can further define a positioning recess 223 (shown in FIG. 4) in a bottom thereof. The first shaft 23 can insert into the first shaft hole 221 and the first fixing hole 140, thereby securing the tray 22 to the first fixing block 14. The tray 22 can rotate about the first shaft 23, thereby allowing the receiving groove 222 to rotate out of the casing 10 through the sliding slot 12.

The limiting assembly 24 can include a limiting member 241 and a first elastic member 242. The limiting member 241 can be slidably received in the blind hole 152, and can include a pin 2412 and a flange 2411 extending around the periphery of a middle of the pin 2412. In at least one embodiment, the first elastic member 242 can be a coil spring coiled around a bottom portion of the pin 2412, and can be positioned between and elastically abuts against the flange 2411 and a bottom of the blind hole 152. When the tray 22 is received in the casing 10, a top portion of the pin 2412 can be inserted into the positioning recess 223 of the tray 22 and elastically abuts against the bottom of the tray 22 under the force of the first elastic member 242, thereby positioning the tray 22 with respect to the second fixing block 15.

The operating member 26 can be rotatably connected to the second fixing block 15, and can push the tray 22 to disengage from the pin 2412 of the limiting member 241 when being rotated. In at least one embodiment, the operating member 26 can include a barrel portion 261, a first arm 262, and a second arm 263. The first arm 261 and the second arm 262 can extend from an exterior wall of the barrel portion 261, and can be angled with each other.

The spacer 25 can be arranged on the accessed portion 151, and can be sandwiched between the tray 22 and the second fixing block 15. The spacer 25 can define a first guiding hole 250 and a second guiding hole 251. The second shaft 27 can be inserted into the barrel portion 261, the second guiding hole 251, and the second fixing hole 153, thereby securing the operating member 26 and the spacer 25 to the second fixing block 15. Thus, the first and the second arms 262, 263 can rotate about the second shaft 27, and the spacer 25 can prevent the limiting member 241 from being disengaged from the blind hole 152 when the limiting member 241 is pushed by the first elastic member 242. Moreover, the top portion of the pin 2412 can insert into the positioning recess 223 of the tray 22 via the first guiding hole 250 of the spacer 25.

When the tray 22 is received in the casing 10, the top portion of the limiting member 241 can be inserted into the positioning recess 223 to position the tray 22 with respect to the second fixing block 15. The first elastic member 242 can be elastically compressed, and the second elastic member 210 can be elastically deformed (see FIGS. 2 and 4).

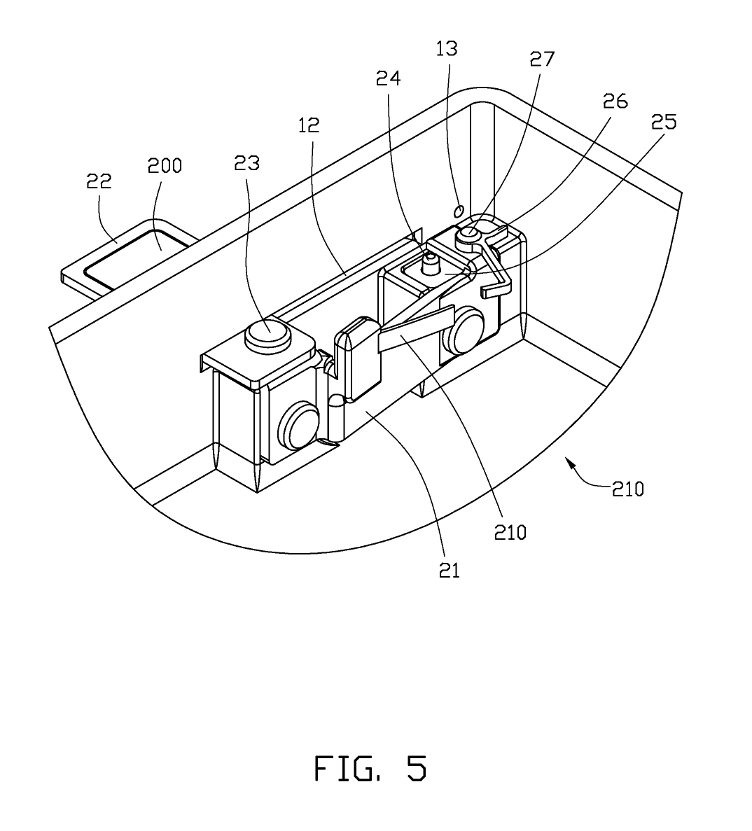

To take out the digital card 200, the first arm 262 of the operating member 26 can be rotated about the second shaft 27 away from the through hole 13, the second arm 263 can be rotated with the first arm 262 and pushes the tray 22 to disengage from the limiting member 241. The second elastic member 210 rebounds pushing the tray 22 to rotate about the first shaft 23, thereby allowing the receiving groove 222 to rotate out of the casing 10 through the sliding slot 12 (FIG. 5). In detail, a user can insert a pin (not shown) into the through hole 13 to force the first arm 262 to rotate.

The described embodiments and their advantages will be understood from the foregoing description. It will be apparent that various changes may be made thereto without departing from the scope of the disclosure or sacrificing all of its material advantages, the examples described merely being exemplary embodiments of the present disclosure. The described embodiments are not intended to limit the scope of the following claims.

What is claimed is:

1. A card loading assembly received in a casing for placing a digital card, the casing defining a sliding slot, the card loading assembly comprising:
a tray able to rotate with respect to the casing, wherein the tray defines a positioning recess and a receiving groove, the receiving groove configured for receiving the digital card and able to rotate out of the casing through the sliding slot; and
a limiting assembly comprising a limiting member and a first elastic member, the limiting member able to be inserted into the positioning recess under a force of the first elastic member when the tray is received in the casing, thereby positioning the tray with respect to the casing.

2. The card loading assembly of claim 1, wherein a first fixing block is attached to a bottom surface of the casing and adjacent to the sliding slot, and the tray is rotatably connected to the first fixing block.

3. The card loading assembly of claim 2, wherein a second fixing block is attached to the bottom surface and adjacent to the sliding slot, the second fixing block defines a blind hole, the limiting member is slidably received in the blind hole, and the first elastic member is positioned between and elastically abuts against the limiting member and a bottom of the blind hole.

4. The card loading assembly of claim 3, further comprising a spacer, wherein the spacer is sandwiched between the tray and the second fixing block, and defines a first guiding hole, the pin inserts into the positioning recess via the first guiding hole, the spacer is able to prevent the limiting member from being disengaged from the blind hole.

5. The card loading assembly of claim 4, wherein the limiting member comprises a pin and a flange extending around a periphery of a substantially middle of the pin, the first elastic member is a coil spring coiled around a bottom portion of the pin, and is arranged between the flange and the bottom of the blind hole, a top portion of the pin inserts into the positioning recess and elastically abuts against a bottom of the tray after being pushed by the coil spring.

6. The card loading assembly of claim 5, further comprising an operating member, wherein the operating member is rotatably seucured to the second fixing block, and is able to push the tray to disengage from the pin of the limiting member when being rotated.

7. The card loading assembly of claim 6, wherein the operating member comprises a first arm and a second arm angled with each other, and the second arm is rotated with the first arm and pushes the tray to disengage from the limiting member.

8. The card loading assembly of claim 7 further comprising a cover, wherein the cover is secured to the first and the second fixing blocks, and comprises a second elastic member aligned with the sliding slot, the second elastic member rebound pushing the tray to rotate when tray disengages from the limiting member, thereby allowing the receiving groove to rotate out of the casing.

9. An electronic device comprising:
a casing comprising a bottom surface and four sidewalls surrounding the bottom surface, one of the four sidewalls defining a sliding slot; and
a card loading assembly received in the casing, and comprising:
a tray able to rotate with respect to the casing, wherein the tray defines a positioning recess and a receiving groove, the receiving groove configured for receiving a digital card and able to rotate out of the casing through the sliding slot; and
a limiting assembly comprising a limiting member and a first elastic member, the limiting member able to be inserted into the positioning recess under a force of the first elastic member when the tray is received in the casing, thereby positioning the tray with respect to the casing.

10. The electronic device of claim 9, wherein a first fixing block is attached to the bottom surface and adjacent to the sliding slot, and the tray is rotatably connected to the first fixing block.

11. The electronic device of claim 10, wherein a second fixing block is attached to the bottom surface and adjacent to the sliding slot, the second fixing block defines a blind hole, the limiting member is slidably received in the blind hole, and the first elastic member is positioned between and elastically abuts against the limiting member and a bottom of the blind hole.

12. The electronic device of claim 11, wherein the card loading assembly further comprises a spacer sandwiched between the tray and the second fixing block, the spacer defines a first guiding hole, the pin inserts into the positioning recess via the first guiding hole, the spacer is able to prevent the limiting member from being disengaged from the blind hole.

13. The electronic device of claim 12, wherein the limiting member comprises a pin and a flange extending around a periphery of a substantially middle of the pin, the first elastic member is a coil spring coiled around a bottom portion of the pin, and is arranged between the flange and the bottom of the blind hole, a top portion of the pin inserts into the positioning recess and elastically abuts against a bottom of the tray after being pushed by the coil spring.

14. The electronic device of claim 13, wherein the card loading assembly further comprises an operating member rotatably secured to the second fixing block, the operating member is able to push the tray to disengage from the pin of the limiting member when being rotated.

15. The electronic device of claim 14, wherein the operating member comprises a first arm and a second arm angled with each other, and the second arm is rotated with the first arm and pushes the tray to disengage from the limiting member.

16. The electronic device of claim 15, wherein the sidewall further defines a through hole, when the first arm is rotated away from the through hole, the second arm pushes the tray to disengage from the limiting member.

17. The electronic device of claim 16, wherein the card loading assembly further comprises a cover, the cover is secured to the first and the second fixing blocks, and comprises a second elastic member aligned with the sliding slot, the second elastic member rebound pushing the tray to rotate when tray disengages from the limiting member, thereby allowing the receiving groove to rotate out of the casing.
